(19) United States
(12) Patent Application Publication
(10) Pub. No.: US 2014/0271057 A1
(43) Pub. Date: Sep. 18, 2014

(54) TEMPERATURE CONTROL SYSTEMS AND METHODS FOR SMALL BATCH SUBSTRATE HANDLING SYSTEMS

(71) Applicant: Applied Materials, Inc., Santa Clara, CA (US)

(72) Inventors: William T. Weaver, Austin, TX (US); Jason M. Schaller, Austin, TX (US); Malcolm N. Daniel, JR., Austin, TX (US); Robert B. Vopat, Austin, TX (US); Jeffrey C. Blahnik, Leander, TX (US); Joseph Yudovsky, Campbell, CA (US)

(21) Appl. No.: 14/212,665

(22) Filed: Mar. 14, 2014

Related U.S. Application Data
(60) Provisional application No. 61/800,595, filed on Mar. 15, 2013.

(51) Int. Cl. H01L 21/677

(52) U.S. Cl. CPC H01L 21/67754
USPC 414/222.02

(57) ABSTRACT

Embodiments of substrate handling systems capable of heating and/or cooling batches of substrates being transferred into and out of various substrate processing chambers are provided. Methods of substrate handling are also provided, as are numerous other aspects.

### RELATED APPLICATIONS

The present application claims priority to U.S. Provisional Patent Application Ser. No. 61/800,595, filed Mar. 15, 2013 and entitled “WAFER HANDLING SYSTEMS AND METHODS FOR SMALL BATCHES OF WAFERS”, (Attorney Docket No. 20667/L/FEG/SYNX), which is hereby incorporated herein by reference in its entirety for all purposes.

### FIELD

The invention relates generally to electronic device manufacturing, and more particularly to temperature control systems and methods for small batch substrate handling systems.

### BACKGROUND

Within an electronic device manufacturing process, a substrate handling system may move substrates into and out of various chambers to undergo processing. Some chambers may simultaneously batch process a relatively small number of substrates (e.g., about six substrates). Some conventional substrate handling systems may be capable of transferring substrates through a manufacturing process at a high throughput, but may only transfer substrates one at a time. This may slow substrate production and, thus, increase the cost of manufacture. Accordingly, improved substrate handling systems and methods capable of transferring small batches of substrates into and out of various chambers are sought.

### SUMMARY

In some aspects of embodiments of the invention, a substrate handling system is provided. The substrate handling system includes a robot configured to transfer a plurality of substrates into or out of a substrate processing chamber; a carousel configured to position the substrates for transfer by the robot; and a temperature control system configured to heat or cool substrates on the carousel.

In other aspects, a method of transferring substrates in a substrate process is provided. The method includes providing a substrate handling system including a robot configured to transfer a plurality of substrates into or out of a substrate processing chamber, a carousel configured to position the substrates for transfer by the robot, and a temperature control system configured to heat or cool substrates on the carousel; loading substrates onto the carousel; heating the substrates on the carousel; and loading the heated substrates into the processing chamber.

In yet other aspects, a substrate processing system is provided. The substrate processing system includes a processing chamber; a substrate handing system coupled to the processing chamber and including a robot configured to transfer a plurality of substrates into or out of the substrate processing chamber, a carousel configured to position the substrates for transfer by the robot, and a temperature control system configured to heat or cool substrates on the carousel; and a factory interface disposed to deliver substrates to the substrate handing system and to receive substrates from the substrate handing system.

Other features and aspects of the invention will become more fully apparent from the following detailed description of example embodiments, the appended claims, and the accompanying drawings.

### BRIEF DESCRIPTION OF THE DRAWINGS

FIG. 1 is a schematic diagram illustrating an example substrate processing system including side-by-side substrate handling carousel style platforms according to embodiments of the present invention.

FIG. 2 is a schematic diagram illustrating an example substrate handling carousel style platform according to embodiments of the present invention.

FIG. 3 is a perspective view diagram illustrating an example substrate handling carousel style platform according to embodiments of the present invention.

FIG. 4 is a perspective view cut-away diagram illustrating an example substrate heating system within a substrate handling carousel style platform according to embodiments of the present invention.

FIG. 5 is a schematic diagram illustrating an example substrate handling carousel style platform including a substrate cooling system according to embodiments of the present invention.

FIG. 6 is a schematic diagram illustrating an example substrate cooling plate for a substrate handling carousel style platform according to embodiments of the present invention.

FIG. 7 is a schematic diagram illustrating an example substrate processing system with a substrate handling carousel style platform including a substrate cooling system and a load lock function according to embodiments of the present invention.

FIG. 8 is a schematic diagram illustrating a substrate processing system with a substrate handling carousel style platform including a substrate heating system and a load lock function according to embodiments of the present invention.

FIG. 9 is a magnified view of the substrate handling carousel style platform of FIG. 8.

FIG. 10 is a flowchart depicting an example method according to embodiments of the present invention.

### DETAILED DESCRIPTION

Embodiments of the present invention relate to temperature control methods and systems for use within substrate handling systems. These substrate handling systems are configured to transfer small batches of substrates (e.g., 5 or 6 substrates) for concurrent processing into or out of a substrate processing chamber or between at least two substrate processing chambers in an electronic device processing system. The substrate processing chambers are capable of processing small batches of substrates simultaneously. Efficient loading and unloading of the substrate batches from the processing chambers is achieved using a carousel style substrate handling system housed in a transfer chamber disposed adjacent the processing chamber(s). Note that in some embodiments, the housing or chamber (e.g., transfer chamber) is considered part of the substrate handling system.

Some embodiments of the substrate handling systems include pre-processing pre-heating and/or post-processing cooling of the substrates within the transfer chamber while the substrates are being moved to or from the processing chamber. Further, some embodiments provide both (a) substrate handing systems with substrate temperature control systems and (b) load lock functions that eliminate the need for a load lock between the substrate handling system/transfer chamber and the factory interface.

Some of the substrate handling system embodiments described herein have a smaller footprint and can also increase substrate throughput over conventional substrate handling systems. These benefits can be achieved via improved load lock utilization since the design decouples operation of the load lock from process chamber loading. In addition, throughput can be improved by providing substrate pre-heating and/or post-process cooling during transfer that does not requiring additional time (e.g., the heating and/or cooling is removed from the “critical path” time calculation because it is performed in parallel with transferring the substrates). Further, some embodiments can provide improved pre-heating control by applying the pre-heating continuously up to the time of entry into the process chamber. Some embodiments described herein are applicable to atomic layer deposition (ALD) carousels.

Turning now to FIGS. 1 and 2, an example embodiment of a substrate processing system 100 including two side-by-side substrate handling carousel style platforms 102 is depicted. The example system 100 includes two small batch processing chambers 104 that are served by the substrate handling carousel style platforms 102, wherein one substrate handling carousel style platform 102 is dedicated to one processing chamber 104. The substrate handling carousel style platforms 102 each include a transfer chamber 106 housing a carousel type substrate handling system 108. As can be more clearly seen in FIG. 2, the substrate handling system 108 includes a transfer robot 110 (e.g., a selective compliance articulated robot arm (SCARA)) supporting an end effector 112 (e.g., a blade) for handing the substrates and a substrate carousel 114 for rotating substrates into position for loading into and unloading from the processing chamber 104 using the transfer robot 110. Note that in some embodiments, a linear extension axis robot arm can be used in place of an articulated robot arm. The substrate carousel 114 is also configured to position the substrates to be passed through a load lock 116 to or from a factory interface robot 118 within a factory interface 120. In some embodiments, the system 100 can also include cooling stations 122 in the factory interface 120.

FIG. 2 depicts a magnified view and FIG. 3 depicts a perspective view of one of the example substrate handling carousel style platforms 102 of FIG. 1. Note that the top of the transfer chamber 106 is removed from FIG. 3 to more clearly show particular features. As shown in FIG. 2, the carousel 114 can include multiple substrate supports 202 (e.g., 5, 6, or 7 supports) that are rotated as the carousel 114 rotates and substrates 302 on one or more of the substrate supports 202 can be heated by one or more stationary heating systems 204 whenever the supports 202 pass proximate to the heating systems 204.

In some embodiments, radiant heating systems can be disposed directly over and/or under substrates 302 on the substrate supports 202 at, e.g., positions immediately proximate to the processing chamber 104. An example of a suitable radiant substrate pre-heater is the RAYMAX® model panel heater commercially available from Watlow Electric Manufacturing Company of St. Louis, Mo. Other practicable heating systems including different types (e.g., conduction or convection) of heaters can be used such as the ULTAMIC® Advanced Ceramic heaters, the Thick Film Conduction heaters, and the Coil & Cable heaters also from Watlow Electric Manufacturing Company. For example, the substrate carousel 114 can include embedded resistive heating elements within one or more of the substrate supports 202 and thus the heating system moves as the carousel 114 rotates. Therefore, the system 100 can be configured to selectively heat substrates 302 in supports 202 rotating toward the processing chamber 104 and not heat the substrates 302 in supports 202 rotating away from the processing chamber 104.

The configuration of the system 100 provides substantial flexibility in the location and use of heaters. Conventionally, preheating was done in the load lock 116. This added time to the process of bringing a substrate 302 to a processing chamber 104. Embodiments of the present invention decouple the load lock function and pre-heating and allow pre-heating to be performed off the critical path timeline. The configuration also allows the use of fewer heaters and the addition or removal of heaters in the field, e.g., for different applications. Further, the system 100 provides improved substrate temperature control by allowing the substrate 302 to be heated until the last moment before loading into the process chamber 104 because the heating system 204 can located directly in front of the process chamber 104. This minimizes the temperature change from the preheat location to the process chamber 104.

FIG. 4 is a perspective view cut-away diagram illustrating an example substrate heating system 204 within a substrate handling carousel style platform 102. The particular example heating system 204 embodiment depicted is positioned as indicated in FIG. 3, above a substrate support 202 of the carousel 114 and adjacent the processing chamber 104. In some embodiments, a radiant heating system 204 that uses and infrared or other wavelength bulb can be used as the heat source 402. In some embodiments, reflectors 404 disposed below the heat source 402 can be used to direct and focus the radiant heat directly at a substrate 302 positioned below the heating system 204 on its way toward the processing chamber 104.

FIG. 5 is a schematic diagram illustrating an example substrate handling carousel style platform 500 including a substrate cooling system 502 according to alternative embodiments of the present invention. The substrate cooling system 502 includes a rotatable carousel 504 supporting one or more cooling plates 506 that act like heat sinks to draw heat away from a substrate 302 resting on one of the cooling plates 506 of the carousel 504. A transfer robot 110 using an end effector 112 is operative to place substrates 302 on the cooling plates 506 after they are unloaded from the processing chamber 104. The carousel 504 can then rotate the cooling substrates 302 to an appropriate position to be loaded into another processing chamber 104′ or into a load lock 116 leading to a factory interface.

FIG. 6 depicts details of an example cooling system 502 including a set of substrate cooling plates 506 mounted on a carousel 504 for use in a substrate handling carousel style platform 500. The cooling plates 506 each include notches 602 and grooves 604 to accommodate features of the end effector 112 when substrates 302 are placed on and removed from the cooling plates 506. In some embodiments, the cooling plates 506 can be made from aluminum, aluminum with copper tubing potted or swaged into the aluminum, nickel plated aluminum, stainless steel or such other materials that have relatively high thermal conductivity. In some embodiments, the plates can include channels for flowing liquid coolant (e.g., water) to further help remove heat.

Likewise, the supporting carousel 504 can also be made from similar materials to help draw away heat from the substrates 302. The dimensions and mass of the cooling plates can be selected to maximize surface contact with the substrates 302 and to provide sufficient heat dissipation/absorption to reduce the temperature of a supported substrate to a desired target temperature within a desired time period. In some embodiments, additional heat sinks can be coupled to the cooling plates 506 and/or the carousel 504. In some embodiments, active cooling systems (e.g., circulated water cooling systems) coupled to the cooling plates 506 and/or the carousel 504 can be used to further enhance cooling.

FIG. 7 is a schematic diagram illustrating an alternative example substrate processing system 700. This example system 700 includes a substrate handling carousel style platform 702 with a substrate cooling system 704 and a load lock function 706 that seals the platform 702 (e.g., using slit valves) and provides a vacuum within the platform 702. In other words, the transfer chamber 708 of the substrate handling carousel style platform 702 is configured to serve as a load lock in addition to being operative to transfer substrates into and out of a processing chamber 710. Note that there is no separate load lock between the factory interface 712 and the transfer chamber 708 of the substrate handling carousel style platform 702. Note that in the example system 700 depicted, a substrate heating station 714 within the factory interface 712 can be used to pre-heat substrates before they enter the transfer chamber 708 and the cooling system 704 can be used to cool substrates after they are removed from the processing chamber 710.

Further note that the example substrate handling carousel style platform 702 of FIG. 7 also includes a linear extension axis robot arm 716 instead of an articulating robot arm. The use of a carousel to position the substrates for loading allows the use of the linear extension axis robot arm 716 that has a lower profile relative to an articulating robot arm. This allows the use of a smaller volume combined load lock and transfer chamber 708 with a shorter pump-down time and thus higher throughput.

Similar to FIG. 7, FIG. 8 depicts a substrate processing system 800 including a substrate handling carousel style platform 802 with a load lock function 804 but instead of a cooling system 704, the embodiment includes a substrate heating system 806. FIG. 9 provides a magnified view of the substrate handling carousel style platform 802 of FIG. 8. Note that the size of transfer chamber 808 of the substrate handling carousel style platform 802 is reduced to minimize the interior dimensions of the chamber 808. This reduces the amount of time required to pump down air pressure in the transfer chamber 808 when the transfer chamber 808 is performing the load lock function. Reduced pump down time results in higher throughput. Note that in the example system 800 depicted, a substrate cooling station 814 within the factory interface 812 can be used to cool substrates after they exit the transfer chamber 808 and the heating system 806 can be used to pre-heat substrates before they are loaded into the processing chamber 810.

Embodiments of the present invention provide methods for controlling the temperature of substrates while transferring the substrates to and from a processing chamber. FIG. 10 depicts an example method 1000 of transferring substrates in a substrate process. The method 1000 includes providing a substrate handling system including a robot configured to transfer substrates into or out of a substrate processing chamber, a carousel configured to position the substrates for transfer by the robot, and a temperature control system configured to heat or cool substrates on the carousel. (1002) Next, the substrates are loaded onto the carousel. (1004) The loaded substrates on the carousel are then pre-heated. (1006) Finally, the heated substrates are loaded into the processing chamber. (1008)

In some embodiments, pre-heating can be performed in the load lock or in the factory interface and post-cooling can be performed in the substrate handling carousel style platform. In alternative embodiments, pre-heating can be performed in the substrate handling carousel style platform and post-cooling can be performed in the load lock or in the factory interface. In yet other embodiments, pre-heating can be performed on a first subset of the substrate supports within the substrate handling carousel style platform and post-cooling can be performed on a second subset of the substrate supports within the substrate handling carousel style platform.

Accordingly, while the invention has been disclosed in connection with example embodiments thereof, it should be understood that other embodiments may fall within the scope of the invention, as defined by the following claims.

The invention claimed is:

1. A substrate handling system, comprising:
a robot configured to transfer a plurality of substrates into or out of a substrate processing chamber;
a carousel configured to position the substrates for transfer by the robot; and
a temperature control system configured to heat or cool substrates on the carousel.

2. The substrate handling system of claim 1 further including a chamber enclosing the substrate handling system.

3. The substrate handling system of claim 1 wherein the carousel includes a plurality of substrate supports and wherein the temperature control system is disposed proximate to at least one substrate support and a processing chamber.

4. The substrate handling system of claim 1 wherein the carousel includes a cooling plate configured to draw heat from the substrates.

5. The substrate handling system of claim 1 wherein the temperature control system includes a radiant heater disposed proximate to at least one substrate support and a processing chamber.

6. The substrate handling system of claim 1 further including a chamber enclosing the substrate handling system and providing a load lock function within the chamber.

7. The substrate handling system of claim 6 wherein the chamber is configured to minimize an internal volume of the chamber.

8. A method of transferring substrates in a substrate process, comprising:
providing a substrate handling system including a robot configured to transfer a plurality of substrates into or out of a substrate processing chamber, a carousel configured to position the substrates for transfer by the robot, and a temperature control system configured to heat or cool substrates on the carousel;
loading substrates onto the carousel;
heating the substrates on the carousel; and
loading the heated substrates into the processing chamber.

9. The method of claim 8 further including providing a chamber enclosing the substrate handling system.

10. The method of claim 8 wherein providing the substrate handing system includes providing a carousel that includes a plurality of substrate supports and disposing the temperature control system proximate to at least one substrate support and the processing chamber.

11. The method of claim 8 wherein providing the substrate handing system includes providing a carousel that includes a cooling plate configured to draw heat from the substrates.

12. The method of claim 8 wherein providing the substrate handing system includes providing the temperature control system having a radiant heater disposed proximate to a substrate support on the carousel and the processing chamber.

13. The method of claim 8 further including providing a chamber enclosing the substrate handling system and performing a load lock function within the chamber.

14. The method of claim 13 wherein the chamber is configured to minimize an internal volume of the chamber.

15. A substrate processing system, comprising:
a processing chamber;
a substrate handing system coupled to the processing chamber and including a robot configured to transfer a plurality of substrates into or out of the substrate processing chamber, a carousel configured to position the substrates for transfer by the robot, and a temperature control system configured to heat or cool substrates on the carousel; and
a factory interface disposed to deliver substrates to the substrate handing system and to receive substrates from the substrate handing system.

16. The substrate processing system of claim 15 wherein the substrate handling system further includes a chamber enclosing the substrate handling system.

17. The substrate processing system of claim 15 wherein the carousel in the substrate handling system includes a plurality of substrate supports and wherein the temperature control system is disposed proximate to at least one substrate support and a processing chamber.

18. The substrate processing system of claim 15 wherein the carousel in the substrate handling system includes a cooling plate configured to draw heat from the substrates.

19. The substrate processing system of claim 15 wherein the temperature control system in the substrate handling system includes a radiant heater disposed proximate to at least one substrate support and a processing chamber.

20. The substrate processing system of claim 15 wherein the substrate handling system further includes a chamber enclosing the substrate handling system configured to provide a load lock function within the chamber, and wherein the chamber is configured to minimize an internal volume of the chamber.
